(19) United States
(12) Patent Application Publication
(10) Pub. No.: US 2025/0192058 A1
(43) Pub. Date: Jun. 12, 2025

(54) SEMICONDUCTOR DEVICE

(71) Applicant: FUJI ELECTRIC CO., LTD., Kanagawa (JP)

(72) Inventors: Atsushi ONOGAWA, Matsumoto-city (JP); Tohru SHIRAKAWA, Matsumoto-city (JP)

(21) Appl. No.: 18/926,285

(22) Filed: Oct. 24, 2024

(30) Foreign Application Priority Data
Dec. 12, 2023 (JP) 2023-209691

(51) Int. Cl. H01L 23/535; H01L 23/532; H01L 29/06; H01L 29/10; H01L 29/40; H01L 29/417; H01L 29/739; H01L 29/78

(52) U.S. Cl. CPC H01L 23/535; H01L 23/53266; H10D 12/481; H10D 30/668; H10D 62/107; H10D 62/393; H10D 64/111; H10D 64/231

(57) ABSTRACT

Provided is a semiconductor device comprising: a semiconductor substrate including an upper surface; an active portion provided on the semiconductor substrate and including a transistor; and a gate runner provided above the upper surface of the semiconductor substrate, wherein the transistor includes a MOS gate including a gate electrode, the gate runner is electrically connected to the gate electrode, and the gate runner is provided between the active portion and one side of the semiconductor substrate above the upper surface of the semiconductor substrate and is not provided between the active portion and any other sides of the semiconductor substrate.

The contents of the following patent application(s) are incorporated herein by reference: NO. 2023-209691 filed in JP on Dec. 12, 2023

### BACKGROUND

### 1. Technical Field

The present invention relates to a semiconductor device.

### 2. Related Art

Conventionally, semiconductor devices provided with gate fingers at the center of their semiconductor bodies are known (see, e.g., Patent Document 1). In addition, semiconductor devices using contact plugs at gate trenches are known (see, e.g., Patent Document 2 or Patent Document 3). Besides these, trench-type MOSFETs using polysilicons having different doping concentrations for gate electrodes of trenches are known (see, e.g., Patent Document 4).

### PRIOR ART DOCUMENT

### Patent Documents

Patent Document 1: Japanese Patent No. 6732715
Patent Document 2: Japanese Patent No. 5975543
Patent Document 3: Japanese Patent Application Publication No. 2009-99872
Patent Document 4: Japanese Patent Application Publication No. 2008-218527

### BRIEF DESCRIPTION OF THE DRAWINGS

FIG. 1 is a top view illustrating an example of a semiconductor device 100 according to one embodiment of the present invention.

FIG. 2 is a view illustrating an A-A′ cross section in FIG. 1.

FIG. 3 is a view illustrating a B-B′ cross section in FIG. 1.

FIG. 4 is a view illustrating a C-C′ cross section in FIG. 1.

FIG. 5 is a view illustrating a D-D′ cross section in FIG. 1.

FIG. 6 is an enlarged view of a region A in FIG. 5.

FIG. 7 is a view illustrating an E-E′ cross section in FIG. 1.

FIG. 8 is a view illustrating another example of the D-D′ cross section in FIG. 1.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention. In the present specification, the same parts in each figure are denoted by the same signs and numerals, and the descriptions thereof may be omitted. In addition, for convenience of description, some configurations may not be illustrated.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using an orthogonal coordinate system of an X axis, a Y axis, and a Z axis. The orthogonal coordinate system merely specifies relative positions of components, and does not limit a particular direction. For example, the Z-axis direction is not limited to illustrating a height direction with respect to the ground. Note that a +Z-axis direction and a −Z-axis direction are directions opposite to each other. When the Z-axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis, respectively. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis and the Y axis.

When a term such as “same” or “equal” is used herein, it may encompass a case where an error due to a variation in manufacturing or the like is included. The error is, for example, within 10%.

In the present specification, a conductivity type of a doping region doped with impurities is described as a P-type or an N-type. In the present specification, the impurities may particularly mean either donors of the N-type or acceptors of the P-type and may be described as dopants. In the present specification, doping means introducing the donors or the acceptors into the semiconductor substrate and turning it into a semiconductor presenting a conductivity type of the N-type, or a semiconductor presenting conductivity type of the P-type.

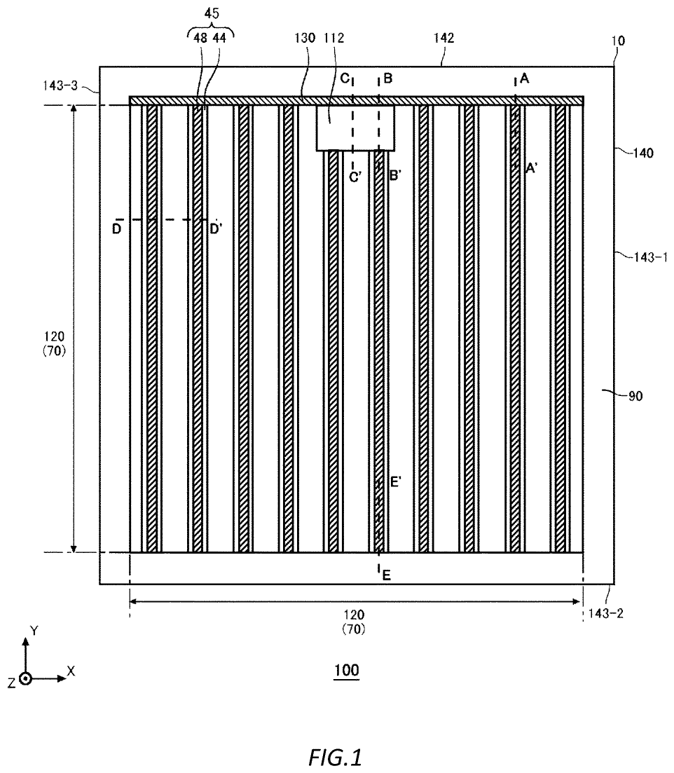

FIG. 1 is a top view illustrating an example of a semiconductor device 100 according to one embodiment of the present invention. FIG. 1 illustrates positions at which respective members are projected on an upper surface of a semiconductor substrate 10. FIG. 1 illustrates merely some of the members of the semiconductor device 100, and omits illustrations of some of the members.

The semiconductor device 100 includes the semiconductor substrate 10. The semiconductor substrate 10 is a substrate formed of a semiconductor material. As an example, the semiconductor substrate 10 is a silicon substrate or a silicon carbide substrate. Ends of an outer perimeter of the semiconductor substrate 10 when viewed in the top view are referred herein to as outer perimeter ends 140. The phrase “when viewed in the top view” refers to a case where an object is seen in parallel with the Z axis from the upper surface side of the semiconductor substrate 10. In addition, any one end side in the outer perimeter ends 140 of the semiconductor substrate 10 when viewed in the top view is referred to as a first end side 142. A direction parallel to the first end side 142 when viewed in the top view is referred to as an X-axis direction, and a direction perpendicular to the first end side 142 is referred to as a Y-axis direction. In addition, sides other than the first end side 142 are referred to as other sides 143. The semiconductor substrate 10 of the present example includes three of the other sides 143-1, 143-2, and 143-3.

The semiconductor substrate 10 is provided with an active portion 120. The active portion 120 is a region through which a main current flows in the depth direction between the upper surface and the lower surface of the semiconductor substrate 10 when the semiconductor device 100 operates. An upper surface electrode, such as a source electrode or an emitter electrode, is provided above the active portion 120, but is omitted in FIG. 1.

The active portion 120 may include a transistor 70. The entire surface of the active portion 120 of the present example is the transistor 70. Only a part of the active portion 120 may be provided with the transistor 70. As an example, the transistor 70 is a MOSFET or an IGBT. A case where the IGBT is provided in the active portion 120 as the transistor 70 is described herein as an example, although a configuration of the active portion 120 is not limited thereto. The active portion 120 may also include a diode.

The active portion 120 may be a portion overlapped with the emitter electrode when viewed in the top view. The emitter electrode may be a pad that is connected to a wire, may be an electrode that is connected to a wire and through which a main current flows, or may be an electrode that is connected to an emitter region of the transistor 70. The emitter electrode may also be connected by welding via a nickel film. In a case where there are a plurality of emitter electrodes, one having a largest area may be the emitter electrode. For example, a pad for current sensing may not be included in the emitter electrode.

The transistor 70 includes a MOS gate including a gate electrode 45. The MOS gate of the present example includes a trench provided on the upper surface of the semiconductor substrate 10, and an interior of the trench is provided with the gate electrode 45. The gate electrode 45 of the present example includes a polysilicon 44 and a metal part 48. In another example, the gate electrode 45 may be entirely the polysilicon 44, or may be entirely the metal part 48. A configuration of the MOS gate will be described below.

In FIG. 1, an arrangement of the metal part 48 and the polysilicon 44 in the active portion 120 is illustrated. When viewed in the top view, the metal part 48 and the polysilicon 44 may extend in a predetermined direction. That is, the trench may also be provided to extend in the predetermined direction when viewed in the top view. The polysilicon 44 and the metal part 48 of the present example extend in the Y-axis direction.

An edge termination structure portion 90 is provided between the active portion 120 and the outer perimeter ends 140 of the semiconductor substrate 10 on the upper surface of the semiconductor substrate 10. The edge termination structure portion 90 may be arranged in a circular pattern to surround the active portion 120 on the upper surface of the semiconductor substrate 10. The edge termination structure portion 90 of the present example is arranged along the outer perimeter ends 140 of the semiconductor substrate 10. The edge termination structure portion 90 reduces an electric field strength on the upper surface side of the semiconductor substrate 10. The edge termination structure portion 90 includes, for example, a guard ring, a field plate, a RESURF and a combination structure of them.

A gate pad 112 is provided above the upper surface of the semiconductor substrate 10. The gate pad 112 is provided between the active portion 120 and the first end side 142. The gate pad 112 may not be included in the active portion.

A gate voltage is applied to the gate pad 112, and the gate voltage is applied to the gate electrode 45 of the MOS gate of the transistor 70 via a gate runner described below. For example, another pad for current sensing may also be provided above the upper surface of the semiconductor substrate 10. The pad may be formed of metal material such as aluminum. A point-to-point construction such as a wire may be connected to an upper surface of the gate pad 112. The gate pad 112 may have a rectangular shape when viewed in the top view.

The semiconductor device 100 includes a gate runner 130 provided above the upper surface of the semiconductor substrate 10. The gate runner 130 is electrically connected to the gate electrode 45. The gate runner 130 is also electrically connected to the gate pad 112 and delivers the gate voltage to the gate electrode 45. The gate runner 130 of the present example is composed of metal. Note that the gate runner 130 may be composed of polysilicon.

The gate runner 130 may be provided between the active portion 120 and one side of the semiconductor substrate 10 above the upper surface of the semiconductor substrate 10 and not be provided between the active portion 120 and any other sides of the semiconductor substrate 10. The gate runner 130 of the present example may be provided only between the active portion 120 and the first end side 142. The gate runner 130 and the gate electrode 45 of the present example are connected only between the active portion 120 and the first end side 142.

The first end side 142 of the present example is a side that is parallel to the X axis. A width of the gate runner 130 in the Y-axis direction may be less than that of the gate pad 112. The width of the gate runner 130 in the Y-axis direction may be equal to or less than half of the width of the gate pad 112 in the Y-axis direction.

A length of the gate runner 130 in the X-axis direction is greater than that of the gate pad 112. The gate runner 130 may be connected to all gate electrodes 45 arranged side-by-side in the X-axis direction in the active portion 120. The gate runner 130 of the present example is provided to extend, among the plurality of gate electrodes 45, from a position facing a gate electrode 45 arranged at one end in the X-axis direction to a position facing a gate electrode 45 arranged at the other end.

In the example in FIG. 1, the gate runner 130 is provided between the gate pad 112 and the first end side 142. In another example, the gate runner 130 may also include a portion provided between the gate pad 112 and the active portion 120. The gate runner 130 may also be provided to surround the gate pad 112 when viewed in the top view. That is, the gate runner 130 may also include a bending portion.

The trench of the present example extends in an extending direction perpendicular to the first end side 142 provided with the gate runner 130 when viewed in the top view (the Y-axis direction). Note that the term “perpendicular” may include a variation of approximately ±10°.

The semiconductor device 100 may further include a well region. The well region may be formed to extend from the upper surface of the semiconductor substrate 10 toward its interior and surround the active portion 120 when viewed in the top view. At least part of the well region may be provided to overlap with the gate runner 130 when viewed in the top view. Note that the well region is not illustrated in FIG. 1.

When the gate voltage is delivered from the gate pad 112 to each gate electrode 45, there occurs a variation in the time it takes for the gate voltage to be delivered due to the resistance of the delivery path. A delay in delivering the gate voltage is referred herein to as the “gate delay”. When the gate delay is large, e.g., at the turn-off of the semiconductor device 100, the time it takes to turn off increases more greatly in a region where the gate delay is large than in a region where the gate delay is small, thereby concentrating currents at the region where the gate delay is large.

In order to reduce the gate delay, various arrangements for the gate runner 130 are contemplated. For example, the gate runner 130 may be provided to surround the active portion 120 along an outer perimeter of the active portion 120. Generally, the gate electrode 45 of the MOS gate is formed of polysilicon, and the gate runner 130 is formed of metal having a specific resistance smaller than that of the polysilicon. Therefore, the gate delay can be reduced by connecting, with the gate electrode 45, the gate runner 130 provided between the active portion 120 and the other sides 143 of the semiconductor substrate 10. However, since an area of the gate runner 130 increases, an area of the active portion 120 unintentionally decreases, or an area of the semiconductor substrate 10 unintentionally increases.

As another example, the gate runner 130 may be provided to traverse across a center of the active portion 120. Thanks to the fact that the gate runner 130 and the gate electrode 45 are connected at the center of the active portion 120, the gate delay can be reduced. However, in this case, the emitter electrode is unintentionally divided into two by the gate runner 130. Then, wires would be bonded to the respective two emitter electrodes, so respective bonding portions would have different resistance values than each other, thereby potentially causing unbalance in current between the respective emitter electrodes or causing oscillation at one of the emitter electrodes.

The gate runner 130 of the present example is provided only between the active portion 120 and the first end side 142, so a ratio of the area of the active portion 120 with respect to the area of the semiconductor substrate 10 can be increased compared to a case where the gate runners 130 are provided at the other sides. Alternatively, the area of the semiconductor substrate 10 having the active portion 120 of the same area can be decreased. Furthermore, in the case of the arrangement of the gate runner 130 in this embodiment, there is only one emitter electrode, so the unbalance in current or bias of the oscillation is not caused.

Note that, in the arrangement of the gate runner 130 in this embodiment, the gate delay may increase. Therefore, the gate electrode 45 of the transistor 70 may include the metal part 48. The configuration of the MOS gate will be described below.

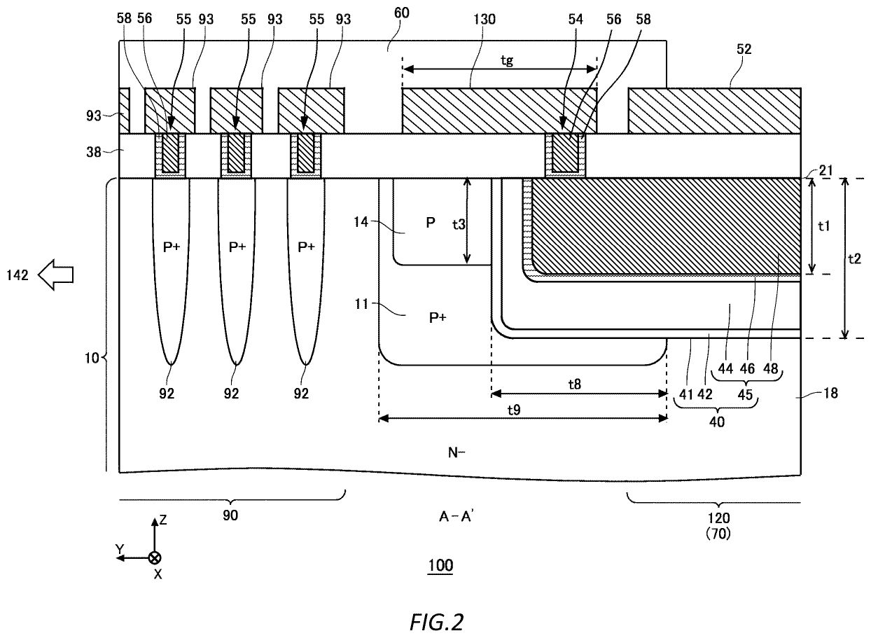

FIG. 2 is a view illustrating an A-A′ cross section in FIG. 1. The A-A′ cross section is a Y-Z cross section that goes through the edge termination structure portion 90, the gate runner 130, and a MOS gate 40 of the transistor 70. When viewed in the A-A′ cross section, the semiconductor device 100 includes the semiconductor substrate 10, an interlayer insulating film 38, an emitter electrode 52, the gate runner 130, a field plate 93, and a protective film 60. The semiconductor substrate 10 has an upper surface 21 and a lower surface. Note that, in FIG. 2 and figures thereafter, configurations on the lower surface side are omitted. There is the first end side 142 on a positive side of the Y-axis direction in the A-A′ cross section.

The semiconductor substrate 10 includes a drift region 18 of a first conductivity type and a channel region 14 of a second conductivity type. The channel region 14 is provided between the drift region 18 and the upper surface 21 of the semiconductor substrate 10. The drift region 18 of the present example is of an N(−)-type and the channel region 14 is of a P-type. The interior of the semiconductor substrate 10 of the present example is provided with the MOS gate 40. The MOS gate 40 controls switching of the transistor 70 depending on an applied gate voltage. The channel region 14 is in contact with the MOS gate 40. The channel region 14 is a region where a channel is formed by an inversion layer of electrons on a surface layer of an interface with the MOS gate 40 when a predetermined gate voltage is applied to the gate electrode 45. A length of the channel region 14 in the depth direction from the upper surface 21 is referred to as t3.

When viewed in the A-A′ cross section, the semiconductor substrate 10 includes a first well region 11 formed at one side of the semiconductor substrate 10 provided with the gate runner 130. The first well region of the present example is provided along the first end side 142. At least part of the first well region 11 is provided between the first end side 142 and the active portion 120 when viewed in the top view. The first well region 11 is provided to extend from the upper surface 21 of the semiconductor substrate 10 to a level deeper than that of the channel region 14. The first well region 11 is a region of a second conductivity type, which has a doping concentration higher than that of the channel region 14. The first well region 11 of the present example is of a P(+)-type. As described above, the semiconductor substrate 10 may be provided with well regions of the p(+)-type surrounding the active portion 120 when viewed in the top view. The first well region 11 may refer to one among the well regions which extends along the first end side 142.

The transistor 70 includes the MOS gate 40 provided from the upper surface 21 of the semiconductor substrate 10 toward its interior. A plurality of MOS gates 40, which are each identical to the MOS gate 40, may be provided as illustrated in FIG. 1. The MOS gates 40 of the present example are arrayed along the X-axis direction and extend in the Y-axis direction. In the present example, the MOS gate 40 is described as a trench gate structure.

The MOS gate 40 includes a trench 41, a gate insulating film 42, and a gate electrode 45. The trench 41 refers to a groove that is provided on the upper surface 21 of the semiconductor substrate 10 and is formed to extend from the upper surface 21 in the depth direction. The trench 41 of the present example reaches as far as the drift region 18. The channel region 14 is in contact with the trench 41. The channel region 14 illustrated in FIG. 2 is in contact with an end of the trench 41 in the Y-axis direction. A length of the trench 41 in the depth direction from the upper surface 21 is referred to as t2. In other words, a length of the MOS gate 40 in the depth direction in FIG. 2 is t2.

The gate insulating film 42 is provided to cover an inner wall of the trench 41. The gate insulating film 42 may be formed by oxidizing or nitriding the semiconductor on the inner wall of the trench 41, or may be formed by a deposition method. The gate electrode 45 is provided in the interior of the trench 41 at an inner side than the gate insulating film 42. That is, the gate insulating film 42 insulates the gate electrode 45 and the semiconductor substrate 10 from each other.

The gate electrode 45 of the present example includes a polysilicon 44 and a metal part 48. Impurities for increasing conductivity may have been implanted in the polysilicon 44. The metal part 48 is formed of metal material. As an example, the metal part 48 includes tungsten. A specific resistance of the metal part 48 is less than a specific resistance of the polysilicon 44. Thanks to the fact that the gate electrode 45 includes the metal part 48 having the lower specific resistance, the above-described gate delay can be reduced.

In the interior of the trench 41, a barrier metal 46 may be provided between the metal part 48 and the polysilicon 44. Then, the barrier metal 46 may also be included in the gate electrode 45. The barrier metal 46 may be formed of metal different than that of the metal part 48. As an example, the barrier metal 46 may include titanium. The barrier metal 46 may have a stack structure of a titanium nitride layer and a titanium layer from the metal part 48 toward the polysilicon 44. Providing the barrier metal 46 can prevent metal elements of the emitter electrode 52 from spreading into the interior of the semiconductor substrate 10.

The metal part 48 may be provided in the interior of the trench 41. In other words, the metal part 48 may be provided in the interior of the semiconductor substrate 10 below the upper surface 21 of the semiconductor substrate 10. A direction from the upper surface 21 of the semiconductor substrate 10 toward the lower surface may be referred herein to as “below”, and a direction opposite thereto may be referred to as “above”. A length of the metal part 48 in the depth direction from the upper surface 21 is referred to as t1. The metal part 48 of the present example is provided to extend to a level deeper than that of the channel region 14. That is, the length t1 is greater than the length t3 of the channel region 14 in the depth direction. Thanks to the fact that the length t1 is greater than the length t3, at least the gate delay in the channel region 14 can be reduced. The length t1 may be 1.1 times or more than the length t3, may be 1.2 times or more than the length t3, may be 1.5 times or more than the length t3, or may be 2 times or more than the length t3.

The MOS gate 40 is not limited to the trench gate structure. The gate electrode 45 of the transistor 70 may include the metal part 48. As an example, the gate electrode 45 of the MOS gate 40 having a planar structure may include the metal part 48. Also in this case, the gate delay can be reduced.

As an example of a method for fabricating the MOS gate 40 of the present example, firstly, the interior of the trench 41 is loaded with the polysilicon 44 via the CVD method. Then, the polysilicon 44 within the trench 41 is etched to form a trench contact, and the trench contact is loaded with tungsten and barrier metal via sputtering. Since a tip of the trench 41 (in a −Z-axis direction) can be thin, it is difficult to load the metal part 48 into the tip of the trench 41. By disposing the polysilicon 44 in the tip portion of the trench 41, a void formation in the tip portion of the trench 41 can be suppressed.

In the MOS gate 40 of the present example, in the interior of the trench 41, the metal part 48 and the polysilicon 44 are stacked. The metal part 48 and the polysilicon 44 may be stacked via the barrier metal 46. In the interior of the trench 41, the metal part 48 and the polysilicon 44 may be stacked in the depth direction. In the present example, the metal part 48 is exposed on the upper surface 21 of the semiconductor substrate 10. The polysilicon 44 is arranged below the metal part 48 in the Z-axis direction. In the interior of the trench 41, the metal part 48 and the polysilicon 44 may be stacked in a horizontal direction (in particular, an array direction of the MOS gate 40) as described below.

The first well region 11 may cover the end of the trench 41 in the extending direction of the trench 41 (the Y-axis direction). The first well region 11 of the present example covers the entire side wall of the end of the trench 41 in the Y-axis direction and a part of a lower surface of the trench 41 extending from the side wall. The channel region 14 may be in contact with the side wall of the trench 41. The first well region 11 may also cover the channel region 14 in contact with the side wall of the trench 41. A length of a portion where the first well region 11 and the trench 41 overlap is referred to as t8. Thanks to the fact that the first well region 11 covers the end of the trench 41, electric field strength at the end of the trench 41 can be reduced.

A width of the first well region 11 in the extending direction of the trench 41 (the Y-axis direction) is referred to as t9. The width T9 is a width of the first well region 11 in the Y-Z cross section, which is not provided with the gate pad 112. A width of the gate runner 130 in the extending direction of the trench 41 (the Y-axis direction) is referred to as tg. The width t9 may be greater than the width tg. When viewed in the top view, at least part of the gate runner 130 may overlap with the first well region 11, or the gate runner 130 may entirely overlap with the first well region 11. Thanks to the fact that the gate runner 130 and the first well region 11 overlap, when viewed in the top view, electric field distribution can be gentle from the end of the trench 41 to the edge termination structure portion 90 outside the gate runner 130. This can reduce a local electric field strength.

In the transistor 70, the emitter electrode 52 is provided above the upper surface 21 of the semiconductor substrate 10. The interlayer insulating film 38 is provided to be in contact with the upper surface 21 of the semiconductor substrate 10 and insulates the gate electrode 45 and the emitter electrode 52. The interlayer insulating film 38 is a film including at least one layer of an insulating film such as silicate glass to which impurities such as boron or phosphorous are added, a thermal oxide film, and other insulating films. The gate runner 130 is provided above the interlayer insulating film 38.

The interlayer insulating film 38 is provided with a contact hole 54 for connecting the gate runner 130 and the gate electrode 45. The contact hole 54 is loaded with the tungsten 56. Therefore, in the semiconductor device 100 of the present example, the gate runner 130 of metal and metal of the gate electrode 45 are directly in contact with each other. Note that the tungsten 56 and a barrier metal 58 described below may be included in the gate runner 130.

The contact hole 54 is provided with the barrier metal 58. The barrier metal 58 of the present example is provided between the tungsten 56 with which the contact hole 54 is loaded and the tungsten of the metal part 48. Providing the barrier metal 58 can prevent metal elements of the emitter electrode 52 from spreading into the interior of the semiconductor substrate 10. The barrier metal 58 may also be provided on a side wall of the contact hole 54.

In the edge termination structure portion 90, the semiconductor substrate 10 is provided with a guard ring 92. The guard ring 92 is a region of the second conductivity type formed by ion-implanting from the upper surface 21 of the semiconductor substrate 10 toward its interior. A doping concentration of the guard ring 92 may be equal to the doping concentration of the first well region 11. A depth of the guard ring 92 may be equal to a depth of the first well region 11.

Also in the edge termination structure portion 90, the interlayer insulating film 38 is provided to be in contact with the upper surface 21 of the semiconductor substrate 10. The field plate 93 is provided above the interlayer insulating film 38. The field plate 93 is formed of metal such as aluminum or conductive material such as polysilicon.

The interlayer insulating film 38 is provided with a contact hole 55 for connecting the field plate 93 and the guard ring 92. As with the transistor 70, the contact hole 55 is provided with the barrier metal 58 and is loaded with the tungsten 56.

The protective film 60 is provided above the interlayer insulating film 38, the emitter electrode 52, the gate runner 130, and the field plate 93. The protective film 60 is formed of polyimide as an example.

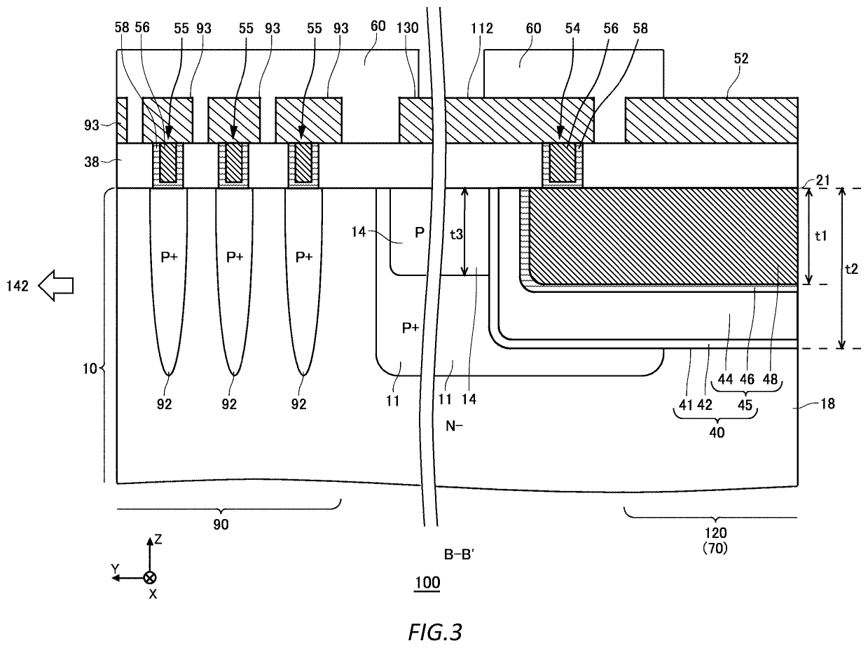

FIG. 3 is a view illustrating a B-B′ cross section in FIG. 1. The B-B′ cross section is a Y-Z cross section that goes through the edge termination structure portion 90, the gate runner 130, the gate pad 112, and the MOS gate 40 of the transistor 70. The B-B′ cross section is different than the A-A′ cross section in that the B-B′ cross section traverses across the gate pad 112. Other aspects are similar to that of the A-A′ cross section, so the description thereof is omitted.

The gate pad 112 is provided above the interlayer insulating film 38. The interlayer insulating film 38 is provided with the contact hole 54 for connecting the gate pad 112 and the gate electrode 45 below the gate pad 112. As with FIG. 2, the contact hole 54 of the present example is also provided with the barrier metal 58 and is loaded with the tungsten 56. Note that part of a region including the gate pad 112 is omitted in FIG. 3. In addition, the protective film 60 of the present example separates in the Y-axis direction above the gate pad 112.

The first well region 11 is formed to extend beyond the active portion 120 side of the gate pad 112. When viewed in the top view, the entire gate pad 112 may overlap with the first well region 11. Also in the B-B′ cross section, the first well region 11 covers the end of the trench 41 in the extending direction.

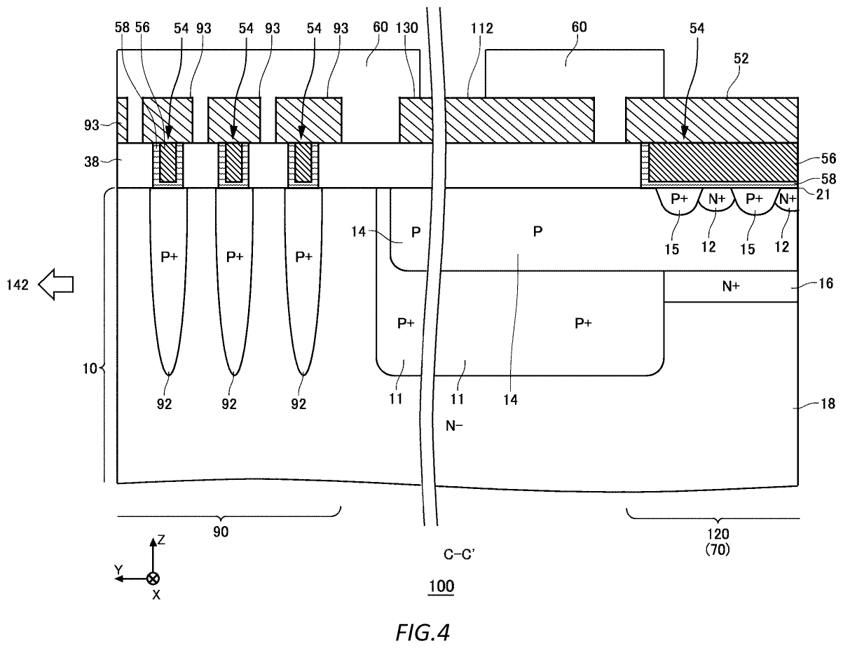

FIG. 4 is a view illustrating a C-C′ cross section in FIG. 1. The C-C′ cross section is a Y-Z cross section that goes through the edge termination structure portion 90, the gate runner 130, the gate pad 112, and a mesa portion of the transistor 70. The mesa portion refers to a region sandwiched between the MOS gates 40 in the transistor 70. The C-C′ cross section is different than the B-B′ cross section in that the C-C′ cross section traverses across the mesa portion. Other aspects are similar to that of the B-B′ cross section, so the description thereof is omitted.

In the mesa portion, the semiconductor substrate 10 includes the channel region 14, the emitter region 12, the contact region 15, and an accumulation region 16. The first well region 11 may be included in the mesa portion at an end of the trench 41 in the extending direction (the Y-axis direction). The first well region 11 and the channel region 14 may be similar to the first well region 11 and the channel region 14 described in FIG. 2. The accumulation region 16 will be described below.

The emitter region 12 is provided between the upper surface 21 of the semiconductor substrate 10 and the channel region 14, and is a region of the first conductivity type having a doping concentration higher than that of the drift region 18. The emitter region 12 of the present example is of an N(+)-type. The contact region 15 is provided between the upper surface 21 of the semiconductor substrate 10 and the channel region 14, and is a region of the second conductivity type having a concentration higher than that of the channel region 14. The contact region 15 in the present example is of the P(+)-type. The emitter region 12 and the contact region 15 are exposed on the upper surface 21. The emitter region 12 and the contact region 15 of the present example are provided to be arranged alternatingly in the extending direction of the trench 41 (the Y-axis direction).

The upper surface 21 of the semiconductor substrate 10 is provided with the interlayer insulating film 38 in the mesa portion. The interlayer insulating film 38 is provided with the contact hole 54 for connecting the emitter electrode 52 as well as the emitter region 12 and the contact region 15. As with FIG. 2, the contact hole 54 of the present example is also provided with the barrier metal 58 and is loaded with the tungsten 56. The contact hole 54 of the active portion 120 extends in the extending direction of the trench 41 (the Y-axis direction).

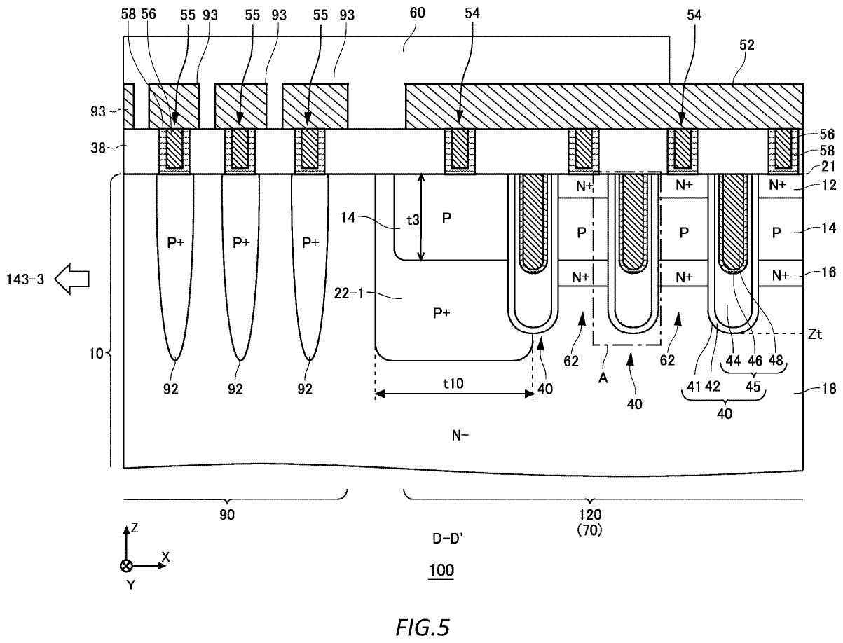

FIG. 5 is a view illustrating a D-D′ cross section in FIG. 1. The D-D′ cross section is an X-Z cross section that goes through the edge termination structure portion 90, and the emitter region 12 of the transistor 70. Since the D-D′ cross section traverses across the other side 143-3 of the semiconductor substrate 10 in FIG. 1, the gate runner 130 is not provided therein. The other side 143-3 is on a minus side of the X-axis direction in the D-D′ cross section. The edge termination structure portion 90 in the D-D′ cross section is similar to the edge termination structure portion 90 illustrated in FIG. 2 to FIG. 4, so the description thereof is omitted.

The interlayer insulating film 38 is provided on the upper surface 21 of the semiconductor substrate 10. The interlayer insulating film 38 of the present example is also provided with the contact hole 54. The interior of the contact hole 54 is provided with the barrier metal 58 and is loaded with the tungsten 56.

The emitter electrode 52 is provided above the interlayer insulating film 38. The emitter electrode 52 electrically connects to the upper surface 21 of the semiconductor substrate 10 through the contact hole 54 in the interlayer insulating film 38. The protective film 60 is provided above the emitter electrode 52 to partially overlap with the emitter electrode 52.

The transistor 70 includes a plurality of MOS gates 40 provided from the upper surface 21 of the semiconductor substrate 10 toward its interior. The MOS gates 40 of the present example are arrayed along the X-axis direction and have their longitudinal directions in the Y-axis direction. As described above, the MOS gate 40 includes the trench 41, the gate insulating film 42, and the gate electrode 45, and the gate electrode 45 includes the polysilicon 44, the barrier metal 46, and the metal part 48. The MOS gate 40 may function as a gate trench, or may function as a dummy trench. Both of the functions may coexist in the plurality of MOS gates 40. A metal part may be provided to the gate electrode 45 of the MOS gate 40 functioning as the dummy trench. By providing the metal part, when the electric potential across the emitter electrode 52 fluctuates, the electric potential distribution among the MOS gates 40 is less likely to occur. Note that the MOS gate 40 functioning as the dummy trench may be provided with the polysilicon 44 instead of the metal part 48.

A mesa portion 62 is provided between the MOS gates 40 of the transistor 70 in the array direction. The mesa portion 62 refers to a region between the MOS gates 40 in the interior of the semiconductor substrate 10. As an example, an upper end of the mesa portion 62 is the upper surface 21 of the semiconductor substrate 10. A depth position of a lower end of the mesa portion 62 is the same as a depth position Zt of the lower end of the trench 41. The mesa portion 62 of the present example is provided to extend in the Y-axis direction along the MOS gate 40 in the upper surface 21 of the semiconductor substrate 10. The mesa portion 62 is provided with the channel region 14.

The transistor 70 includes the emitter region 12 provided on the upper surface 21. The emitter region 12 is exposed on the upper surface 21 of the semiconductor substrate 10 and is provided to be in contact with the MOS gate 40. The emitter region 12 may be in contact with the MOS gates 40 at both sides of the mesa portion 62. When the D-D′ cross section traverses across the contact region 15, the emitter region 12 in FIG. 5 is replaced with the contact region 15.

The channel region 14 is provided below the emitter region 12. The channel region 14 of the present example is provided to be in contact with the emitter region 12. The channel region 14 may be in contact with the MOS gates 40 at both sides of the mesa portion 62.

The accumulation region 16 is provided below the channel region 14. The accumulation region 16 is a region of the first conductivity type having a doping concentration higher than that of the drift region 18. The accumulation region 16 of the present example is of the N(+)-type. By providing the accumulation region 16 having a high concentration between the drift region 18 and the channel region 14, a carrier injection enhancement effect (IE effect) can be enhanced and an ON voltage can be reduced. The accumulation region 16 may be provided to cover the entire lower surface of the channel region 14 in each mesa portion 62.

As described above, the metal part 48 is provided to be at a level deeper than that of the channel region 14 in the depth direction. The metal part 48 of the present example is provided to extend to a position in the depth direction where the metal part 48 overlaps with the accumulation region 16. The metal part 48 may be provided to be at a level deeper than that of the accumulation region 16.

The outer perimeter of the active portion 120 is provided with a second well region 22-1. The second well region 22-1 is a region of the second conductivity type provided to extend from the upper surface 21 of the semiconductor substrate 10 to its interior. A doping concentration of the second well region 22-1 may be equal to that of the first well region (see FIG. 2 to FIG. 4). A depth at which the second well region 22-1 is provided may be equal to a depth at which the first well region is provided. The first well region 11 and the second well region 22 provided at each side may be connected at corners of the semiconductor device 100.

A width of the second well region 22-1 in a direction perpendicular to the other side 143-3 (the X-axis direction) is referred to as t10. The width t10 may be less than the width t9 of the first well region 11. As described above, the gate runner 130 is not provided between the active portion 120 and the other side 143-3. Therefore, the width t10 can be less than the width t9. This can increase the ratio of the area of the active portion 120 with respect to the area of the semiconductor substrate 10. Alternatively, the area of the semiconductor substrate 10 having the active portion 120 of the same area can be decreased.

A difference between the width t10 and the width t9 may be half or more of the width tg of the gate runner 130 (see FIG. 2). When the entire gate runner 130 overlaps with the first well region 11, the difference between the width t10 and the width t9 may be equal to or more than the width tg of the gate runner 130.

The second well region 22 may also be provided in a cross section from the edge termination structure portion 90 at the other side 143-1 to the active portion 120. A relationship between the width of the second well region 22 and the width t9 of the first well region 11 may be similar to a relationship between the width t10 and the width t9.

The second well region 22-1 may be in contact with a MOS gate 40 provided on the outermost side of the active portion 120 or may cover the MOS gate 40. The second well region 22-1 of the present example is in contact with approximately half of the MOS gate 40.

The interlayer insulating film 38 may include the contact hole 54 between the MOS gate 40 provided on the outermost side of the active portion 120 and the edge termination structure portion 90. In the present example, the emitter electrode 52 and the second well region 22-1 are electrically connected via the contact hole 54.

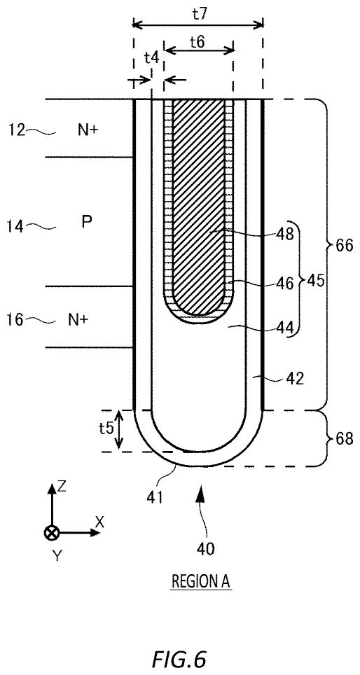

FIG. 6 is an enlarged view of a region A in FIG. 5. The region A is a region including the MOS gate 40, the emitter region 12, the channel region 14, and the accumulation region 16.

The trench 41 may include a side wall 66 and the bottom portion 68. The side wall 66 may be a wall of the trench 41 extending from the upper surface 21 to the depth of the channel region 14 or may be the wall of the trench 41 perpendicular to the upper surface 21. Note that, typically, since the wall of the trench 41 may not be exactly perpendicular to the upper surface 21, the term “perpendicular” may have a variation of approximately ±10°. The bottom portion 68 may be a portion of the trench 41 other than the side wall 66. The bottom portion 68 of the present example is a curved portion at the tip of the trench 41. The bottom portion 68 may be a portion in which a tangent in the X-Z cross section forms a gradient greater than 10° with respect to a normal to the upper surface 21. In FIG. 6, the side wall 66 is shown by bold lines.

The polysilicon 44 of the present example is provided between the side wall 66 of the trench 41 and the metal part 48. Generally, when the material of the gate electrode 45 is changed, the threshold voltage changes. Therefore, by providing the polysilicon 44 between the side wall 66 and the metal part 48, a variation in the threshold voltage due to providing the metal part 48 can be suppressed. In addition, since voids are likely to be formed in the tungsten of the metal part 48, when the metal part 48 is in contact with the side wall 66, a portion where no channel is formed due to the voids may be made unintentionally. On the other hand, no void is formed in the polysilicon 44. Therefore, the channel can be formed across the entire surface of the channel region 14. The polysilicon 44 may be provided entirely between the side wall 66 of the trench 41 and the metal part 48. In other words, the metal part 48 may not be in contact with the side wall 66. In a direction perpendicular to the side wall 66 of the trench 41 that goes through the emitter region 12 (the X-axis direction), the polysilicon 44 and the metal part 48 may be stacked.

A thickness of the polysilicon 44 stacked with the metal part 48 in the direction perpendicular to the side wall 66 (the X-axis direction) is referred to as t4. In other words, the thickness t4 is a thickness of the polysilicon 44 provided between the side wall 66 and the metal part 48. The thickness t4 may be 0.2 μm or less. Even if the thickness t4 is slight, an effect of suppressing the variation in the threshold voltage described above is produced. The thickness t4 may be 0.1 μm or less. The thickness t4 may be 0.05 μm or more.

A thickness of the polysilicon 44 formed in the bottom portion 68 in the depth direction of the trench 41 is referred to as t5. The thickness t5 may be greater than the thickness t4. As described above, the polysilicon is likely to be loaded into the tip of the trench 41. In addition, since the IE effect becomes larger and the ON voltage can become lower as the trench 41 gets deeper, the trench 41 is formed to extend to a level deeper than that of the channel region 14. However, the metal part 48 may not be provided to extend to as far as the bottom portion 68. As a result, the polysilicon 44 of the bottom portion 68 gets thicker.

A width of the metal part 48 and the barrier metal 46 in the direction perpendicular to the side wall 66 (the X-axis direction) is referred to as t6. A width of the trench 41 in the direction perpendicular to the side wall 66 (the X-axis direction) is referred to as t7. The width t7 is greater than the width t6. This enables to provide the polysilicon 44 between the side wall 66 and the metal part 48. The width t6 is 0.5 μm or more and 1 μm or less, as an example.

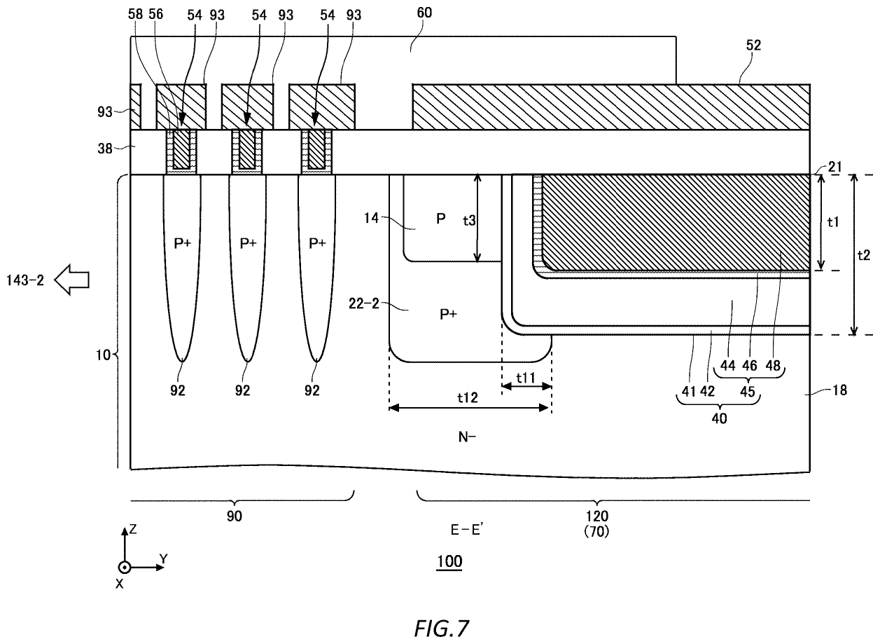

FIG. 7 is a view illustrating an E-E′ cross section in FIG. 1. The E-E′ cross section is a Y-Z cross section that goes through the edge termination structure portion 90, and the MOS gate 40 of the transistor 70. Differences from the A-A′ cross section (FIG. 2) will be described below.

Since the E-E′ cross section traverses across the other side 143-2 of the semiconductor substrate 10 in FIG. 1, the gate runner 130 is not provided therein. The other side 143-2 is on a minus side of the Y-axis direction in the E-E′ cross section. In addition, a second well region 22-2 is provided along the other side 143-2. A doping concentration and a depth of the second well region 22-2 may be similar to those of the second well region 22-1 (see FIG. 5).

A width of the second well region 22-2 is referred to as t12. The width t12 may be less than the width t9 of the first well region 11. As described above, the gate runner 130 is not provided between the active portion 120 and the other side 143-2. Therefore, the width t12 can be less than the width t9. This can increase the ratio of the area of the active portion 120 with respect to the area of the semiconductor substrate 10. Alternatively, the area of the semiconductor substrate 10 having the active portion 120 of the same area can be decreased.

A difference between the width t12 and the width t9 may be half or more of the width tg of the gate runner 130 (see FIG. 2). When the entire gate runner 130 overlaps with the first well region 11, the difference between the width t12 and the width t9 may be equal to or more than the width tg of the gate runner 130.

The second well region 22-2 overlaps with the end of the trench 41 in the extending direction of the trench 41. A length of a portion where the second well region 22-2 and the trench 41 overlap is referred to as t11. The length t8 of the portion where the first well region and the trench 41 overlap (see FIG. 2) may be greater than the length t11. Since the gate runner 130 is not provided in the E-E′ cross section, the gate electrode 45 of the MOS gate 40 does not electrically connect to other electrodes and the like in this cross section. On the other hand, the gate runner 130 and the gate electrode 45 are connected in the portion where the first well region 11 and the trench 41 overlap (see FIG. 2). Therefore, an electric field tends to concentrate at the portion where the first well region 11 and the trench 41 overlap.

Note that the gate runner may also be provided in the E-E′ cross section. That is, the gate runner may be provided between the active portion 120 and the other side 143-2 along the other 143-2 of the semiconductor substrate 10. The gate runner may connect to the gate electrode 45 of each MOS gate 40. The gate runner does not connect to the gate runner 130 provided along the first end side 142 illustrated in FIG. 1 and the like.

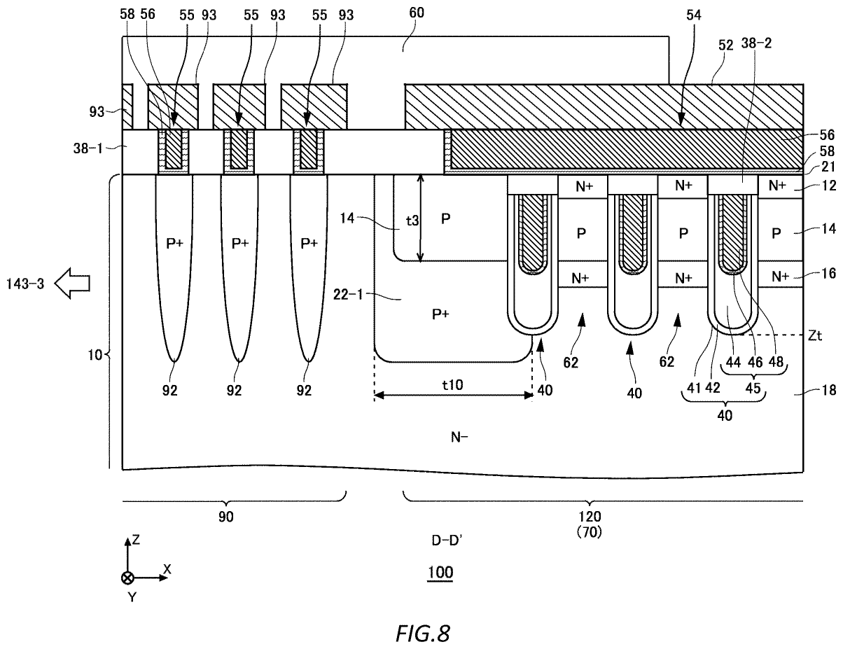

FIG. 8 is a view illustrating another example of the D-D′ cross section in FIG. 1. The D-D′ cross section of the present example is different than the D-D′ cross section illustrated in FIG. 5 in the arrangement of the interlayer insulating film 38. Other aspects are similar to that in FIG. 5, so the description thereof is omitted.

The semiconductor device 100 of the present example is provided with the interlayer insulating film 38-1 and the interlayer insulating film 38-2. The interlayer insulating film 38-1 is provided above the upper surface 21 of the semiconductor substrate 10 to extend from the edge termination structure portion 90 to the active portion 120. The interlayer insulating film 38-2 is provided in the active portion 120. The interlayer insulating film 38-2 insulates the gate electrode 45 of the MOS gate 40 and the emitter electrode 52. The interlayer insulating film 38-2 of the present example is provided in the interior of the trench 41. At least part of the interlayer insulating film 38-2 may be provided in the interior of the trench 41, or the entire interlayer insulating film 38-2 may be provided in the interior of the trench 41. In accordance with this, the contact hole 54 of the present example is provided across a plurality of mesa portions 62. By providing the interlayer insulating film 38-2 in the interior of the trench 41, a required precision of positioning when forming the contact hole 54 can be lower, and miniaturization of the mesa portion 62 can be easier.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the description of the claims that the embodiments added with such alterations or improvements can be included the technical scope of the present invention.

What is claimed is:

1. A semiconductor device comprising:
a semiconductor substrate including an upper surface;
an active portion provided on the semiconductor substrate and including a transistor; and
a gate runner provided above the upper surface of the semiconductor substrate, wherein
the transistor includes a MOS gate including a gate electrode,
the gate runner is electrically connected to the gate electrode, and
the gate runner is provided between the active portion and one side of the semiconductor substrate above the upper surface of the semiconductor substrate and is not provided between the active portion and any other sides of the semiconductor substrate.

2. The semiconductor device according to claim 1, wherein the gate electrode of the transistor includes a metal part.

3. The semiconductor device according to claim 2, wherein
the MOS gate includes a trench provided on the upper surface of the semiconductor substrate, and
the metal part is provided in an interior of the trench.

4. The semiconductor device according to claim 3, wherein the semiconductor substrate includes:
a drift region of a first conductivity type; and
a channel region of a second conductivity type provided between the upper surface of the semiconductor substrate and the drift region, and in contact with the trench, and wherein
the metal part is provided to extend to a level deeper than that of the channel region.

5. The semiconductor device according to claim 4, wherein the metal part and polysilicon are stacked in the interior of the trench.

6. The semiconductor device according to claim 5, wherein
the trench includes a side wall and a bottom portion, and
the polysilicon is provided between the side wall of the trench and the metal part.

7. The semiconductor device according to claim 6, wherein a thickness of the polysilicon stacked with the metal part in a direction perpendicular to the side wall is 0.2 μm or less.

8. The semiconductor device according to claim 6, wherein a thickness of the polysilicon formed in the bottom portion in a depth direction of the trench is greater than a thickness of the polysilicon provided between the side wall and the metal part.

9. The semiconductor device according to claim 3, further comprising:
an emitter electrode provided above the upper surface of the semiconductor substrate; and
an interlayer insulating film which insulates the gate electrode and the emitter electrode,
wherein the interlayer insulating film is provided in the interior of the trench.

10. The semiconductor device according to claim 3, wherein the metal part includes tungsten.

11. The semiconductor device according to claim 5, wherein in the interior of the trench, a barrier metal of metal different than the metal part is provided between the metal part and the polysilicon.

12. The semiconductor device according to claim 11, the barrier metal includes titanium.

13. The semiconductor device according to claim 10, further comprising:
an emitter electrode provided above the upper surface of the semiconductor substrate; and
an interlayer insulating film which insulates the gate electrode and the emitter electrode, wherein
the interlayer insulating film is provided with a contact hole for connecting the gate runner and the gate electrode,
the contact hole is loaded with tungsten, and
a barrier metal is provided between the tungsten with which the contact hole is loaded and the tungsten of the metal part.

14. The semiconductor device according to claim 3, further comprising:
a well region surrounding the active portion when viewed in a top view, and formed to extend from the upper surface of the semiconductor substrate toward its interior to a level deeper than that of the trench, wherein
the well region includes:
a first well region formed at one side of the semiconductor substrate provided with the gate runner; and
a second well region formed at least one side of other sides not provided with the gate runner, and
a width of the second well region is less than a width of the first well region.

15. The semiconductor device according to claim 14, wherein a difference between a width of the second well region and a width of the first well region is half or more of a width of the gate runner.

16. The semiconductor device according to claim 14, wherein
the trench extends in an extending direction perpendicular to the one side of the semiconductor substrate provided with the gate runner when viewed in the top view,
the first well region and the second well region overlap with an end of the trench in the extending direction, and
a length of a portion where the first well region and the trench overlap is greater than a length of a portion where the second well region and the trench overlap.

17. The semiconductor device according to claim 4, further comprising:
a well region surrounding the active portion when viewed in a top view, and formed to extend from the upper surface of the semiconductor substrate toward its interior to a level deeper than that of the trench, wherein
the well region includes:
a first well region formed at one side of the semiconductor substrate provided with the gate runner; and
a second well region formed at least one side of other sides not provided with the gate runner, and
a width of the second well region is less than a width of the first well region.

18. The semiconductor device according to claim 5, further comprising:
a well region surrounding the active portion when viewed in a top view, and formed to extend from the upper surface of the semiconductor substrate toward its interior to a level deeper than that of the trench, wherein
the well region includes:
a first well region formed at one side of the semiconductor substrate provided with the gate runner; and
a second well region formed at least one side of other sides not provided with the gate runner, and
a width of the second well region is less than a width of the first well region.

19. The semiconductor device according to claim 6, further comprising:
a well region surrounding the active portion when viewed in a top view, and formed to extend from the upper surface of the semiconductor substrate toward its interior to a level deeper than that of the trench, wherein
the well region includes:
a first well region formed at one side of the semiconductor substrate provided with the gate runner; and
a second well region formed at least one side of other sides not provided with the gate runner, and
a width of the second well region is less than a width of the first well region.

20. The semiconductor device according to claim 7, further comprising:
a well region surrounding the active portion when viewed in a top view, and formed to extend from the upper surface of the semiconductor substrate toward its interior to a level deeper than that of the trench, wherein
the well region includes:
a first well region formed at one side of the semiconductor substrate provided with the gate runner; and
a second well region formed at least one side of other sides not provided with the gate runner, and
a width of the second well region is less than a width of the first well region.
